(19) United States
(12) Patent Application Publication
(10) Pub. No.: US 2022/0349789 A1
(43) Pub. Date: Nov. 3, 2022

(54) METHOD TO PREPARE A SAMPLE FOR ATOM PROBE TOMOGRAPHY (APT), PREPARATION DEVICE TO PERFORM SUCH METHOD AND METHOD TO INVESTIGATE A REGION OF INTEREST OF A SAMPLE INCLUDING SUCH PERFORMING METHOD

(71) Applicant: Carl Zeiss SMT GmbH, Oberkochen (DE)

(72) Inventors: Sascha Christian Mueller, Heidenheim an der Brenz (DE); Marcus Kaestner, Wittislingen (DE); Cheryl Hartfield, Plano, TX (US)

(21) Appl. No.: 17/344,367

(22) Filed: Jun. 10, 2021

Related U.S. Application Data
(60) Provisional application No. 63/180,700, filed on Apr. 28, 2021.

(51) Int. Cl. G01N 1/44; G01N 1/32

(52) U.S. Cl. CPC G01N 1/44; G01N 1/32; H01J 37/285

(57) ABSTRACT

To prepare a sample for atom probe tomography, a raw sample body having a surface and a region of interest (ROI) to be inspected by APT is provided. Pillars containing the ROI are formed into the surface of the raw sample body via ablation of material of the raw sample body from the surface with an ultra-short pulsed laser. Redeposited ablated material is removed in the region of the formed pillars. The surface of the formed pillars is polished. A preparation device to perform such a preparation method includes a sample handling unit, a pillar forming unit including an ultra-short pulsed laser, a removal unit to remove redeposited ablated material, and a polishing unit. The result is an efficient preparation of robust samples for atom probe tomography. To investigate a region of interest of a sample, the preparation method is performed and then atom probe tomography of the region of interest is performed.

### CROSS-REFERENCE TO RELATED APPLICATION

This application claims priority under 35 U.S.C. § 119(e)(1) to U.S. Provisional Application No. 63/180,700, filed Apr. 28, 2021. The content of this application is hereby incorporated by reference in its entirety.

### FIELD

The disclosure relates to a method to prepare a sample for atom probe tomography (APT). The disclosure also relates to a preparation device to perform such a method. The disclosure further relates to a method to investigate a region of interest of a sample prepared according to such a method, including performing atom probe tomography of the region of interest of the sample.

### BACKGROUND

APT sample preparation is known from: Halpin, J. E., Webster, R. W. H., Gardner, H., Moody, M. P., Bagot, P. A. J., MacLaren, D. A. An in-situ approach for preparing atom probe tomography specimens by xenon plasma-focused ion beam. Ultramicroscopy. 2019; 202, 121-127; Gault B, Moody M P, Cairney J M, Ringer S P. Atom Probe Microscopy: Springer New York; 2012; Ulfig, R. M., Geiser, B. P., Larson, D. J., Kelly, T. F., Prosa, T. J. (2013). Local Electrode Atom Probe Tomography: A User's Guide. Netherlands: Springer New York; and Forbes, R. G., Miller, M. K. (2014). Atom-Probe Tomography: The Local Electrode Atom Probe. United States: Springer US.

### SUMMARY

The disclosure seeks to provide an efficient preparation of robust samples for atom probe tomography.

In a general aspect, the disclosure provides a method to prepare a sample for atom probe tomography (APT), including the following steps: providing a raw sample body having a surface and at least one region of interest (ROI) to be inspected by APT; forming pillars containing the ROI into the surface of the raw sample body via ablation of material of the raw sample body from the surface with an ultra-short pulsed laser; removing redeposited ablated material in the region of the formed pillars; and polishing the surface of the formed pillars.

According to the disclosure, it has been recognized that use of an ultra-short pulsed laser to form pillars into the surface of the raw sample body leads to an efficient sample preparation for atom probe tomography. The finally resulting prepared sample may have a high quality, smooth surface with no significant topography or projections.

The pillars hereinafter also are referred to as needles.

The ultra-short pulsed laser used to form the pillars during the sample preparation method may have a wavelength in the infrared (IR), near infrared (NIR) or visible region. For example, IR and green wavelengths may be used. The laser can use femtosecond pulses to ensure a reduced heat-affected zone. A suitable such laser is known from https://www.zeiss.com/microscopy/int/cmp/mat/20/nanomaterials/fslaser/laserfib.html.

The ultra-short pulsed laser may have the following laser parameters: wavelength 515 nm, pulse duration <500 fs, pulse peak power 20 MW, spot size <15 μm (1 μm=1 um).

The region of interest (ROI) to be inspected by APT may be on the surface or below the surface of the raw sample body.

The use of an ultra-short pulsed laser in the APT specimen preparation workflow can enable rapid removal of large material volumes, which can enable creation of needle-shaped APT samples that remain integrated within their original substrate. This type of APT specimen may withstand electrostatic stresses when undergoing field ionization during the atom probe tomography experiment. The laser may be used to create coarse pillars, the size of which can affect the speed of subsequent charged particle polishing steps to create the final needle shape. To improve the efficiency of these polishing steps, the laser-cut pillars may have a typical cross section and/or diameter which is less than 100 um, such as in a range of 10 to 50 μm. Such cross section/diameter dimension may be in the range between 10 μm and 100 μm, for example in the range between 30 μm and 40 μm. The initial laser-cut pillar sidewalls may have larger slopes than used for the final specimen, since FIB (focused ion beam) may be used to tailor an ideal slope in the final polishing steps. When all workflow steps to form the pillars are completed, a final slope of the pillar sidewalls may be so small that opposing pillar sidewalls are nearly parallel and, for example, have an angle to each other which is 10 to 15 degrees at most, such as a range of 6 to 10 degrees. It is not necessary to shape the entire coarse pillar into a needle shape, for example, if a very long pillar has been created. When all steps to form the pillars, for example, the laser ablation and polishing steps are completed, it is desirable for the atom probe needle to have its tip project a sufficient distance (on the order of tens of microns up to 100 um) above any flat or broad surface, to avoid interfering with field emission at its tip during the APT experiment. The polishing step may be done with charged particles, such as generated via a focused ion beam (FIB).

Focused ion beams can be used to perform final shaping of the atom probe specimen into a sharp tip with diameter <200 nm, such as between 50-100 nm diameter. Ions may be delivered via inductively-couple plasma FIB sources, liquid metal ion sources, liquid metal alloy ion sources, cold atom ion sources, gas field ion sources, or plasma ion sources. Typically Ga+ and sometimes Xe+ ions are used. In that respect, reference is made to FIG. 13 of Nabil Bassim, John Notte, Focused Ion Beam Instruments, Materials Characterization, Vol 10, 2019 ed., ASM Handbook, ASM International, 2019, p 635-670 Additional description of a needle shape fabricated by FIB can be found in Forbes, R. G., Miller, M. K. (2014), Atom-Probe Tomography: The Local Electrode Atom Probe. United States: Springer US.

The laser ablation preparation steps may be performed in a vacuum environment or with a controlled partial pressure of a desired gas, such as nitrogen or argon, as well as others.

Pillars of chosen dimensions may be formed via ablation by choosing ultra-short pulsed laser and system parameters that balance between the desired characteristics of high throughput (fast ablation), with the desired characteristics of high sample quality, which is generally characterized by having minimal laser redeposited material resulting from the ablation. The laser chamber's pressure is included as a parameter that can be controlled, across a range of pressures from ambient down to 10⁻⁶ mbar.

Additional shaping of coarse pillars may be accomplished by FIB, by plasma FIB (PFIB) and/or by use of a laser. A final needle shape may involve a FIB, such as using Ga⁺ ions or a PFIB, using Xe⁺ and/or other ions. To remove millimetres of material, the laser may have a high throughput.

Plasma focused ion beam (PFIB) or FIB processing may be optimized to avoid forming redeposited material on the final sample structures.

Final pillar/needle height may be 20 um to 100 um (above the flat surface created by removing material around the pillar).

Sufficient pillar spacing may be desired, if making a 1D or 2D array, to avoid field ionization effects from neighbors, as is known from the references cited above.

The dimensions of the coarse pillar may be optimized to balance the speed of subsequent FIB polish (thicker laser-cut pillars will take longer to FIB polish) with the level of re-cast/ablated material (severity is affected by the speed and amount of material removed).

Clearing all substrate material between pillars in a 1D array can enable correlative TEM-sample dimensions depend on thickness tolerance of a TEM holder of a respective preparation/inspection device.

A substrate material may be cleared from a given pillar to each edge so that a clear line of site can be established to view a chosen pillar perpendicular to a line array of pillars.

The laser work may be performed in a controlled partial pressure environment or vacuum to minimize laser redeposited material from falling onto the sample or important system components.

Recast and redeposited laser ablation by-products may be removed by performing cleaning steps prior to doing the final FIB shaping, to avoid topographical surfaces that negatively impact field ionizations.

Cleaning the laser recast material from the sample may be done by at least one of the following strategies:
spin-coating a photoresist layer may be done prior to the laser ablation step. After the laser work, the photoresist layer may be removed by plasma or chemicals such as NMP (1-methyl-2-pyrrolidone);
an electron or ion beam deposited protection layer may be used, which can serve as a sacrificial layer, prior to the laser work. After the laser work, this is removed by tilting the sample so the interface between the protection layer and the sample is orthogonal to the FIB beam, providing access to remove it by FIB milling parallel to its surface. Other angles for FIB access to remove the sacrificial layer are possible, contingent upon the angle allowing removal of an undesired portion of ablated recast material, while preserving the atom probe area of interest from accidental milling or removal. This will vary depending on pillar diameters, volume/thickness of recast material, and depth of the target ROI below the surface; and
sonication or a “CO₂ snow jet” may be used to clean off the laser ablated material before doing final FIB polishing. This can be done even without using a sacrificial layer or protection layer. Sonication is described generally in https://www.toppr.com/guides/physics/waves/what-is-sonication/.

The CO₂ snow jet is a cleaning process based upon the controlled expansion of either liquid or gaseous carbon dioxide. This expansion leads to the nucleation of small dry ice particles and a high velocity carrier gas stream. Upon impact with a surface, the dry ice removes particles of all sizes by momentum transfer, and hydrocarbons and organics via a transient solvent or a freeze fracture mechanism. The high-velocity gas can blow the contaminants away. CO₂ snow jet cleaning is described in https://tectra.de/sample-preparation/snow-jet-cleaning/.

In some embodiments, prior to forming the pillars, a sacrificial layer (SL) is deposited at least on a part of the surface of the raw sample body, and at least part of the sacrificial layer is removed after the forming of the pillars. Such sacrificial layer deposition and removal can facilitate removal of redeposited ablated material. In general, the sacrificial layer is a layer added knowing that it later can be removed on purpose. The sacrificial layer may aid the removal of laser recast/redeposit material and/or may provide contrast enabling identification of an original sample surface prior to laser processing. When removing the sacrificial layer, a small portion may be left on purpose. Such residual sacrificial layer portion may be desirable for APT of a surface layer. In this case, the sacrificial layer may be the same material as the material of a capping layer. The sacrificial layer may be a photoresist material and/or a protective layer deposited by charged particle beams. Such layers are known, for example from Utke I, Hoffmann P, Melngailis J. Gas-assisted focused electron beam and ion beam processing and fabrication, Journal of Vacuum Science & Technology B: Microelectronics and Nanometer Structures. 2008; 26(4). It may even be the ink of a permanent marker. In that respect reference is made to Park, Y. C., Park, B. C., Romankov, S., Park, K. J., Yoo, J. H., Lee, Y. B., Yang. J.-M. Use of permanent marker to deposit a protection layer against FIB damage in TEM specimen preparation, Journal of Microscopy 255. 2014. p. 180-187. In some cases, the upper layer of the sample itself is a sacrificial layer, for example, if the region of interest for atom probe inspection is far beneath the top surface.

To produce the sacrificial layer, any of the commonly available gas chemistries available in FIB may be used, depending on sample properties and desire to match reasonably closely the evaporation fields between the sample and capping layer. Generally, this may be the case if only a portion of the sacrificial layer is removed, and a small amount will remain on the surface, as would be desired for an analysis of the original surface of a sample. Common FIB precursors available include Trimethyl(methylcyclopentadienyl)platinum(IV), naphthalene, and tungsten hexacarbonyl. Alternately, a film may be applied by physical vapor deposition using, for example, nickel, or one may spin-coat a photoresist.

In some embodiments, the sacrificial layer is deposited by charged particle deposition. Such sacrificial layer deposition has been proven to be efficient. Such charged-particle beam-induced deposition using electrons or ions may be done in a FIB-SEM instrument.

In some embodiments, the sacrificial layer is removed via laser ablation, ion milling, wet chemistry, plasma, a mechanical mechanism, such as lifting a Si mask. Such removal variants have proven to be efficient. With respect to “lifting a Si mass”, reference is made to Subramaniam S, Smath L, Brown A, Johnson K. Use of Single Crystal Masks for Improved Mill Characteristics in High Current Xenon Plasma FIB instrumentation, Microscopy and Microanalysis. 2016; 22(53):152-3. Further reference is made to slides 14-16 at https://www.eu-f-n.org/ems/wp-content/uploads/2017/07/tutorial_joakimreuteler_fib-artifacts-and-hot-to-overcome-them_2017-05-24.pdf.

In some embodiments, a femtosecond laser is used to form the pillars. Such an approach has been proven to achieve good ablation results with respect to spatial resolution and with respect to unwanted energy deposition. Unnecessary heating of the sample body during the pillar formation step is avoided.

In some embodiments, during the forming of the pillars, a region of the surface around the pillars in a radius which is larger than five times the height of the pillars is cleared. Such a clearing step can facilitate the atom probe tomography inspection of the respective pillars. As a result, in the surrounding of the pillars, no disturbing structures are present.

In some embodiments, after the removal of the redeposited ablated material a protection layer is applied. Such a protection layer, which also is referred to as a capping layer, can avoid unwanted chemical reactions of the surface with the region of interest, in particular avoiding an oxidisation of such surface.

In general, a protection layer is a layer added to the surface of the sample to protect it from ion beam erosion from stray ions during focused ion milling.

A protection or capping layer may have additional desired properties unique to APT. Such protection layer can protect the sample surface. Also, it may be desirable to apply such protection or capping layer choosing a material with similar field ionisation potential as the actual sample.

A purpose of the protection layer may be to protect the surface from ion beam erosion (stray ions) during the shaping of the atom probe tip. Such protection or capping layer can be advantageous to achieve the desired needle shape without destroying the top surface in the process. It can allow fine tuning of the parameters during processing, allowing one to visualize the progress of tip shaping and defining the point at which you are about to remove sample material instead of ‘capping’ material. The capping material, if it re-mains on the shaped needle tip when initiating the APT analysis, may be closely matched to the sample's field ionization properties. With respect to the capping layer, reference is made to Ulfig, R. M., Geiser, B. P., Larson, D. J., Kelly, T. F., Prosa, T. J. (2013), Local Electrode Atom Probe Tomography: A User's Guide, Netherlands: Springer New York, p. 25.

The protection layer may be the same material as used for the sacrificial layer. Optionally, one may pick a material fulfilling one, some or all of the following criteria at least to a certain degree: good adhesion, similar evaporation field as the specimen, different mass spectrum peak than sample, very large grain size or amorphous cap to help avoid inducing topography during FIB polishing, and lower or similar sputtering rate to the specimen.

In some embodiments, all preparation steps are done automatically. Such Automation of the preparation method can lead to a very efficient and reproducible preparation method.

The disclosure also seeks to provide a preparation device to perform such preparation method.

In a general aspect, the disclosure provides a preparation device to perform a method as describe herein. The preparation device includes: a sample handling unit; a pillar forming unit including an ultra-short pulsed laser to form pillars in a surface of the sample; a removal unit to remove redeposited ablated material in the region of the formed pillars; and a polishing unit to polish the sample surface in the region of the formed pillars

The advantages of such preparation device can correspond to those which have been discussed above with respect to the preparation method.

The disclosure further seeks to provide an investigation method to investigate a region of interest of the sample.

In a general aspect, the disclosure provides a method to investigate a region of interest of a sample, including the following steps: performing a method to prepare the sample as described herein; and performing atom probe tomography (APT) of the region of interest. The advantages of such an investigation method can correspond to those discussed with respect to the preparation method and/or with respect to the preparation device.

Features and functions which are disclosed, explained and discussed throughout this application, throughout this specification, may be combined in any form resulting in further methods and in further devices which also may be subjects of disclosures to be claimed.

### BRIEF DESCRIPTION OF THE DRAWINGS

Illustrative embodiments of the disclosure are now described with reference to the figures, in which.

FIG. 1 shows an upper view of a sample prepared for atom probe tomo-graphy (APT);

FIG. 2 shows a sectional view according to section line II-II in FIG. 1;

FIG. 3 shows schematically a preparation device to perform a method to prepare the sample according to FIGS. 1 and 2;

FIG. 4 a schematical flow chart showing an embodiment of a sample preparation method; and

FIG. 5 another schematical flow chart showing another embodiment of the sample preparation method.

### DESCRIPTION OF ILLUSTRATIVE EMBODIMENTS

A sample 1 is prepared for inspection with atom probe tomography (APT). The sample 1 can be cut from a silicon wafer. The sample 1 can include a handling section 2 and a sample pillar section 3. The handling section 2 can be used for handling the whole sample 1. At the handling section 2, for example, a tweezer of a sample handling unit 4 of a preparation device 5 as shown schematically in FIG. 3 can grip the sample 1.

A total thickness T of the sample 1 may be equal to the initial wafer thickness is approximately 0.8 mm. A typical width dimension W of the sample handling unit 4 is 3 to 5 mm.

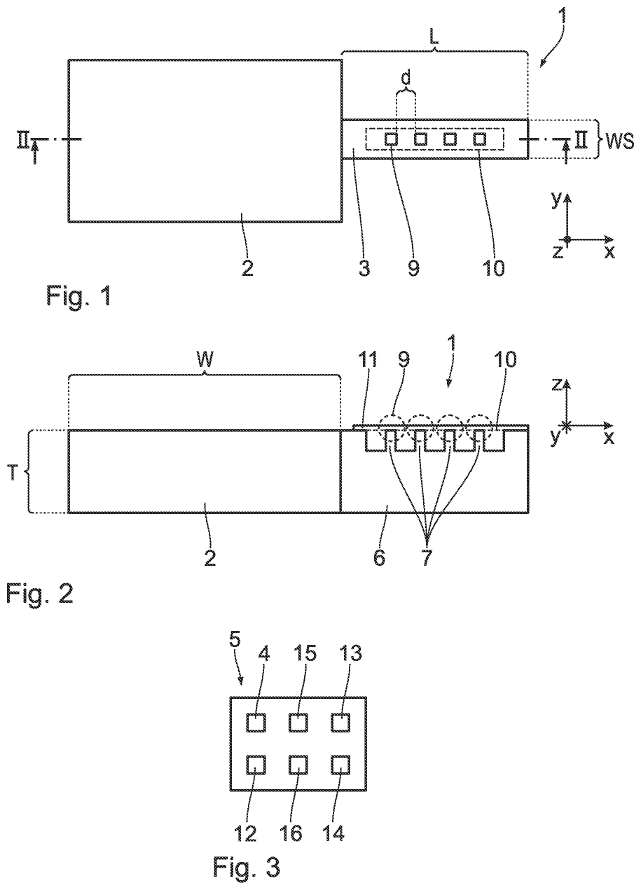

The sample pillar section 3 can have a base body 6 with an elongated contour (FIG. 1) with a length L of about 2 mm and a width WS of about 0.5 mm.

In the sample pillar section 3, a plurality of pillars 7 extends from the base body 6.

To facilitate the description of orientations and dimensions, in the following a Cartesian coordinate system is used. In FIG. 1, the x-axis is directed to the right and the y-axis is directed upwards. The z-axis extends perpendicular to the drawing plane of FIG. 1 in the direction to the viewer.

The pillars 7 can have an extension of approximately 50 μm in the z-direction. The pillars 7 generally have the shape of a needle. They can have an approximately square cross section with an extension of 10 μm in the x- and in the y-direction. Opposing side walls 8 of the pillars 7 can be approximately parallel to each other. Alternatively, a slide conical angle in the range between 1 deg and 10 deg is possible. Alternative to a square xy-cross section, the pillars 7 may have a rounded and/or circular cross section with a typical diameter of 10 μm.

The pillars 7 can be arranged in a row which extends in the x-direction. Alternatively, the pillars may be arranged in a xy-array.

In the FIG. 1/FIG. 2 embodiment, the sample 1 has a total of four pillars 7. Depending on the desired APT parameters, alternative embodiments of the sample 1 may have a number of pillars 7 in the range between 1 and 1000, for example between 1 and 100, such as between 1 and 50.

A distance d between adjacent pillars 7 can be 300 μm, i.e. is more than five times the z height of the respective pillar 7. The distance d is not shown in scale as compared to the z height of the pillars shown in FIG. 2. The distance d may, depending on the respective embodiment, vary between 50 μm and 1 mm.

In the whole area surrounding the neighbouring pillars 7, the material of the base body 6 is removed. The result of such clearance is that between adjacent pillars 7 there is free space and the respective pillars 7 are the structures with by far the largest height as compared to the surrounding base body 6. A typical xy-dimension of such clearance is com-parable to the distance d.

Highlighted via dashed circles in FIG. 2 are regions of interest ROI 9 for APT. Further, these regions of interest 9 also are highlighted in the upper view of FIG. 1. The region of interest 9 may include a stack of material layers.

In a method to prepare the sample 1, initially a raw sample body can be provided having a surface 10 (cf. FIGS. 1 and 2) with the region of interest 9 to be inspected by APT. Such raw sample body provision may be done by cutting a wafer in a base body shape as shown in the upper view of FIG. 1 including the handling section 2 and a raw sample section having the contour of sample pillar section 3 in FIG. 1. In some embodiments, the sample can be adapted to dimensions similar to that of a standard TEM grid, for example, with a 3 mm diameter in length, less than 3 mm in height, and a thickness no greater than that compatible with fitting into a TEM sample holder (typically, no more than 100 um).

After the raw sample body provision, the pillars 7 are formed into the surface 10 of the raw sample body via ablation of material of the raw sample body from the surface 10 with an ultra-short pulsed laser. A typical xy-cross section or diameter value of the pillars 7 may be smaller than 20 The ultra-short pulsed laser to be used to form the pillars 7 may be an fs- (femtosecond) laser or a ps- (picosecond) laser.

During the forming of the pillars 7, a region of the surface 10 around the pillars 7 in a radius, which can be more than 5 times the height of the pillars, is cleared.

Prior to forming the pillars 7, a sacrificial layer SL 11 may be deposited at least on a part of the surface 10 of the raw sample body. After the forming of the pillar 7, at least part of such sacrificial layer SL may be removed. The sacrificial layer SL may be deposited by charged particle deposition. Such deposition may be done by use of a FIB-SEM referred to in https://www.zeiss.com/microscopy/int/cmp/mat/20/nanomaterials/fslaser/laserfib.html. Such an instrument is also is referred to as a Crossbeam laser or referred to as a laser FIB.

The source of unwanted redeposition comes from the sample itself, so the redeposited material is sample dependent. Examples for the protective, cap and sacrificial layers are given in C. Kang, C. Chandler, and M. Weschler, Chap. 3, Gas Assisted Ion Beam Etching and Deposition, Focused Ion Beam Systems, N. Yao, Ed., Cambridge University Press, 2007.

Beam-induced deposition may be done with any charged particle beam (electrons or ions). Chapter 3 of the Yao book above describes deposition. FIB redeposition and FIB deposition further are mentioned elsewhere in the Yao book. More details on deposition are in section 3.3 of Yao's book.

The sacrificial layer 11 may be a resist capping layer and/or a charged-particle beam-induced protective layer. It can also be a Si mask as described in: Subramaniam S, Smath L, Brown A, Johnson K. Use of Single Crystal Masks for Improved Mill Characteristics in High Current Xenon Plasma FIB instrumentation. Microscopy and Microanalysis. 2016; 22(53):152-3.

After the forming of the pillars 7, redeposited ablated material in the region of the formed pillars 7, and in particular, in the cleared region of the surface 10, is removed. Part of such removal step may be the removal of at least part of the sacrificial layer 11 from the structure remaining after the ablation process step. Such sacrificial layer removal serves at least partly to remove the redeposited ablated material.

The removal of the sacrificial layer 11 may be done via laser ablation or via ion milling or via wet chemistry or plasma, or via a combination of at least two of these removal techniques. A Si mask may be lifted off or removed in a sonication bath.

After the removal step of the redeposited ablated material, and prior to any polishing steps, the surface of the sample is polished in the region of interest 9. The polishing may be done with a focused ion beam (FIB).

After the removal of the redeposited ablated material, a protection layer may be applied to the region of interest 9. Such application of the protection layer is done before polishing of the region of interest 9.

Such preparation method may be done in a vacuum environment. During the preparation method, all preparation steps may be performed automatically. For navigation of the sample during the preparation method, correlative microscopy might be used including SEM and TEM or STEM.

In a further embodiment, a protection layer may be deposited on the surface 10 with the region of interest 9 prior to form the pillars 7.

The preparation device 5 includes besides the sample handling unit 4 a pillar forming unit 12 including the ultra-short pulsed laser to form the pillars 7 in the surface 10 of the sample 1. A removal unit 13 of the preparation device 5 serves to remove the redeposited ablated material in the region of the formed pillars 7. A polishing unit 14 serves to polish the sample surface 10 in the region of the formed pillars 7. The polishing unit 14 may include an ion beam source and further a focusing optics to focus the generated ion beam.

Further, the preparation device 5 may include a deposition unit 15 to deposit the sacrificial layer 11 at least on a part of the sample surface 10 prior to the formation of the pillars 7. Further, the preparation device 5 may include a sacrificial layer removal unit 16 to remove at least part of the sacrificial layer 11 from the sample surface 10.

In a method to investigate the region of interest 9 of the sample 1, initially the above described method to prepare the sample 1 is performed. After that, atom probe tomography (APT) of the region of interest 9 is performed.

With APT, 3D tomography is done at atomic resolution.

To prepare the region of interest 9, fiducials or other positioning markers may be placed on the sample 1. This may be done by use of a laser or a charged particle beam.

A preparation of the sample 1 may be done from the front side, but alternatively may be done from the back side of the sample 1. This in particular is done in case of a wafer having a thickness T which is less than 100 μm.

The APT inspection may be combined with SEM/TEM (scanning electron microscopy/transmission electron microscopy), in particular with scanning transmission electron microscopy (STEM). The cleared material around the pillars can enable the TEM to have a clear line of site, i.e. a clear, unobstructed path, for transmitting electrons from the source, through the ROI, to the detector.

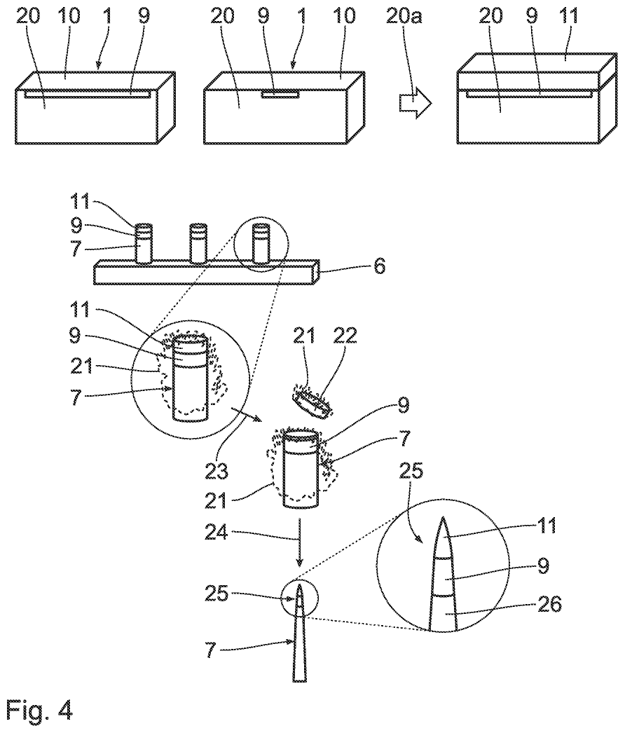

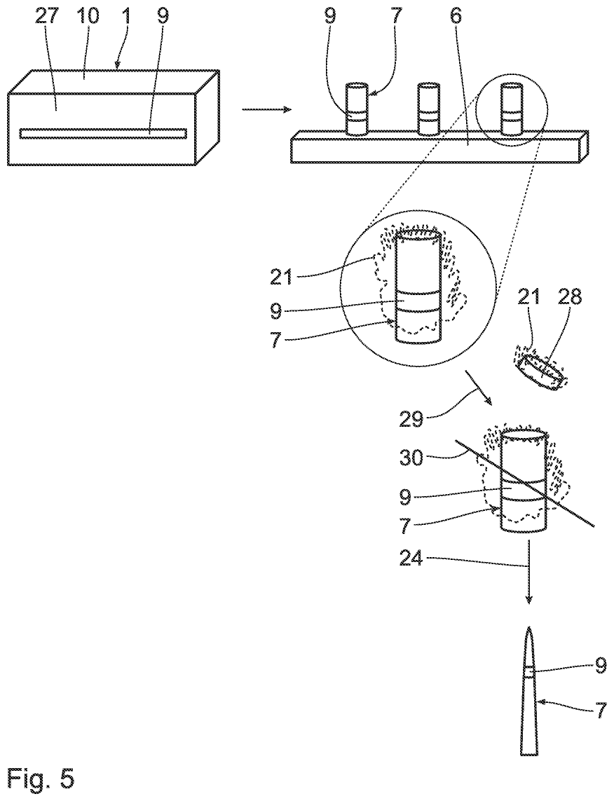

FIGS. 4 and 5 show schematical flow charts of embodiments of the method to prepare a respective sample 1 to form pillars 7 for APT inspection.

In an initial step, the raw sample body 20 having the surface 10 and having the at least one region of interest (ROI) 9 to be inspected is provided. FIG. 4 shows two different examples for such raw sample bodies 20. The raw sample body 20 as shown on the left hand side in the head area of FIG. 4 has an extended region of interest 9 directly at the surface 10. The other raw sample body 20 shown right next to it has a smaller ROI 9 being located at a distance to the surface 10. A distance between the ROI 9 and the surface 10 may be a few μm, e.g. maybe 10 μm at most.

After the provision of the raw sample body 20, the sacrificial layer 11 is deposited on the surface 10 of the raw sample body 20. A respective deposition step is indicated at 20a in FIG. 4.

After that, the pillars 7 in an initial coarse shape which may be cylindrical are formed into the surface 10 of the raw sample body 20 via ablation of material of the raw sample body 20. This forming of the coarse shaped pillars 7 is done with an ultra-short pulse (USP) laser. An intermediate product showing the base body 6 and three of such coarsely shaped pillars 7 is shown in FIG. 4 in a second line. At the top of such coarsely shaped pillars 7 there is a layer showing the ROI 9 capped by the sacrificial layer 11. Further, FIG. 4 shows a detail enlargement of one of these coarsely shaped pillars 7 showing in addition laser recast/redeposit material 21, which is recast/redeposited on the surface of the coarse pillar 7.

In a next preparation step, at least a portion or a part 22 of the sacrificial layer 11 is removed as shown at removal step 23 in FIG. 4. Such removal may be done via laser ablation, via ion milling, via plasma ash or another suitable removal process as described above. With such removal step 23 also at least a portion of the laser recast/redeposit material 21 is removed.

After the removal step 23, in a polishing step 24 the coarsely shaped pillar 7 is polished to prepare the final needle shaped pillar 7, which is shown at the bottom of FIG. 4. Such polishing is done with a focused ion beam (FIB). FIG. 4 further shows a detail enlargement of a needle tip 25 of the needle pillar 7 showing the layer structure of a needle body 26, the ROI 9 and the sacrificial layer 11 at the very end of the needle tip 25. Such final needle has a high quality, smooth surface with no significant topography or projections.

Removal of the part 22 of the sacrificial layer 11 avoids that during the subsequent polishing an undesired, not smooth surface results in the top portion of the resulting needle pillar.

FIG. 5 shows a variant of the preparation method in case a raw sample body 27 is present having the ROI 9 more deeply buried into its body volume. In this case, a distance between the surface 10 and the ROI 9 is more than a few μm, e.g. more than 10 μm or more than 25 μm.

Components, functions and steps of such preparation method variant which have been described with reference to the other fig. and in particular with reference to FIG. 4 show the same reference numerals and are not discussed in detail again.

In that case, after forming the coarse pillars 7 on the base body 6, which is done similar to the FIG. 4 case (compare FIG. 5 top right and the detail enlargement below), laser re-cast/redeposit material 21, which may include a cap layer 28, is removed from the coarse pillar 7 in a removal step 29. This also is done via laser ablation or ion milling. As indicated in the part of FIG. 5 showing the removal step 29, such removal may be done perpendicular to a cylinder axis of the coarse pillar 7 or may be done at an oblique angle as indicated at 30.

After the removal step 29, the polishing step 24 takes place as discussed above, in particular with respect to FIG. 4. The result of such polishing step 24 in FIG. 5 is the final needle shaped pillar 7 having the ROI 9 in the region of its needle tip.

In the FIG. 5 preparation method no sacrificial layer deposit takes place. Instead of the removal of the portion or the part 22 of the sacrificial layer 11, in the FIG. 5 preparation method the cap layer 28 is removed from the top of the coarse pillar 7. This again avoids a low quality top surface region of the resulting needle shaped pillar 7.

What is claimed is:

1. A method of preparing a sample for atom probe tomography, the method comprising:
providing a raw sample body having a surface and a region of interest (ROI) to be inspected via APT;
using an ultra-short laser to ablate material from the raw sample body to form pillars containing the ROI;
removing redeposited ablated material in a region of the pillars; and
polishing the surface of the pillars.

2. The method of claim 1, further comprising prior to forming the pillars, forming a sacrificial layer (SL) on a portion of the surface of the raw sample body.

3. The method of claim 2, further comprising, after forming the pillars, removing a portion of the SL.

4. The method of claim 3, comprising using a member selected from the group consisting of laser ablation, ion milling, wet chemistry, plasma, a mechanical mechanism to remove the portion of the SL.

5. The method of claim 4, comprising using charged particle deposition to form the SL.

6. The method of claim 2, comprising using charged particle deposition to form the SL.

7. The method of claim 2, wherein the ultra-short laser comprises a femtosecond laser.

8. The method of claim 2, further comprising, during formation of the pillars, clearing a region of the surface around the pillars.

9. The method of claim 2, further comprising, after removing the redeposited ablated material, applying a protection layer.

10. The method of claim 2, wherein the method is performed automatically.

11. The method of claim 2, further comprising performing atom probe tomography of the ROI.

12. The method of claim 1, wherein the ultra-short laser comprises a femtosecond laser.

13. The method of claim 1, further comprising, during formation of the pillars, clearing a region of the surface around the pillars.

14. The method of claim 13, wherein a radius of the region of the surface around the pillars is more than five times a height of the pillars.

15. The method of claim 1, further comprising, after removing the redeposited ablated material, applying a protection layer.

16. The method of claim 1, wherein the method is performed automatically.

17. The method of claim 16, further comprising performing atom probe tomography of the ROI.

18. The method of claim 1, further comprising performing atom probe tomography of the ROI.

19. A preparation device, comprising:
a sample handling unit;
a pillar forming unit comprising an ultra-short pulsed laser configured to form pillars in a surface of a sample;
a removal unit configured to remove redeposited ablated material in a region of the pillars; and
a polishing unit configured to polish the sample surface in the region of the pillars.

20. The preparation device of claim 19, further comprising:
a deposition unit configured to deposit a sacrificial layer (SL) on a portion of the sample surface prior to forming the pillars; and
an SL removal unit configured to remove a portion of the SL from the sample surface.
